(19) United States
(12) Patent Application Publication
(10) Pub. No.: US 2023/0141595 A1
(43) Pub. Date: May 11, 2023

(54) COMPENSATION METHODS FOR VOLTAGE AND TEMPERATURE (VT) DRIFT OF MEMORY INTERFACES

(71) Applicant: Advanced Micro Devices, Inc., Santa Clara, CA (US)

(72) Inventors: Aaron D Willey, Hayward, CA (US); Karthik Gopalakrishnan, Cupertino, CA (US); Pradeep Jayaraman, San Jose, CA (US)

(73) Assignee: Advanced Micro Devices, Inc., Santa Clara, CA (US)

(21) Appl. No.: 17/855,066

(22) Filed: Jun. 30, 2022

Related U.S. Application Data
(60) Provisional application No. 63/276,950, filed on Nov. 8, 2021.

(51) Int. Cl. G06F 1/08; G11C 11/4076

(52) U.S. Cl. CPC G06F 1/08; G11C 11/4076; G11C 11/406

(57) ABSTRACT

A data processing system includes a data processor coupled to a memory. The data processor includes a reference clock generation circuit for providing a reference clock signal, a first delay circuit for delaying the reference clock signal by a first amount to provide a command and address signal, a second delay circuit for delaying the reference clock signal by a second amount to provide a read data signal, a calibration circuit for determining current values of the first and second amounts, and a compensation circuit for calculating drifts in the first and second amounts based on a measured temperature change, at least one voltage sensitivity coefficient, and at least one temperature sensitivity coefficient, and for updating the first and second amounts according to the drifts.

This application claims priority to provisional application U.S. 63/276,950 filed Nov. 8, 2021, the entire contents of which are incorporated herein by reference.

### BACKGROUND

Modern dynamic random-access memory (DRAM) provides high memory bandwidth by increasing the speed of data transmission on the bus connecting the DRAM and one or more data processors, such as graphics processing units (GPUs), central processing units (CPUs), and the like. In one example, graphics double data rate (GDDR) memory has pushed the boundaries of data transmission rates to accommodate the high bandwidth needed for graphics applications. In order to ensure the correct reception of data, modern GDDR memories have required extensive training prior to operation to make sure that the receiving circuit can correctly capture the data. Over time, however, GDDR data transmission systems experience voltage and temperature (VT) drift, which cause the optimum points for the delays to change such that re-training must be performed periodically, which causes the system to have to stall operation while performing the retraining.

### BRIEF DESCRIPTION OF THE DRAWINGS

FIG. 1 illustrates in block diagram for a data processing system that compensates for VT drift according to some embodiments;

FIG. 2 illustrates in block diagram form a GDDR PHY-DRAM link of the data processing system of FIG. 1 according to some embodiments;

FIG. 3 illustrates in block diagram form an annotated GDDR PHY-DRAM link corresponding to the GDDR PHY-DRAM link of FIG. 2;

FIG. 4 illustrates a timing diagram useful in understanding the operation of the operation of the data processing system of FIG. 2; and

FIG. 5 illustrates another timing diagram useful in understanding the operation of the data processing system of FIG. 2.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

A data processing system includes a data processor coupled to a memory. The data processor includes a reference clock generation circuit for providing a reference clock signal, a first delay circuit for delaying the reference clock signal by a first amount to provide a command and address signal, a second delay circuit for delaying the reference clock signal by a second amount to provide a read data signal, a calibration circuit for determining current values of the first and second amounts, and a compensation circuit for calculating drifts in the first and second amounts based on a measured temperature change, at least one voltage sensitivity coefficient, and at least one temperature sensitivity coefficient, and for updating the first and second amounts according to the drifts.

A data processor adapted to be coupled to a memory includes a reference clock generation circuit, a first delay circuit, a second delay circuit, a calibration circuit, and a compensation circuit. The reference clock generation circuit provides a reference clock signal. The first delay circuit delays the reference clock signal by a first amount to provide a command and address signal. The second delay circuit delays the reference clock signal by a second amount to provide a read data signal. The calibration circuit determines current values of the first and second amounts. The compensation circuit calculates drifts in the first and second amounts based on a measured temperature change, at least one voltage sensitivity coefficient, and at least one temperature sensitivity coefficient, and for updating the first and second amounts according to the drifts.

A method for a data processor to update timing values for accessing a memory to compensate for voltage and temperature (VT) drift during operation without performing link retraining includes generating a reference clock signal. The reference clock signal is delayed by a first amount using a first delay circuit to provide a command and address signal. The reference clock signal is delayed by a second amount using a second delay circuit to provide a read data signal. Current values of said first and second amounts are determined using a calibration circuit. Drifts in said first and second amounts are calculating based on a measured temperature change, at least one voltage sensitivity coefficient, and at least one temperature sensitivity coefficient using a compensation circuit.

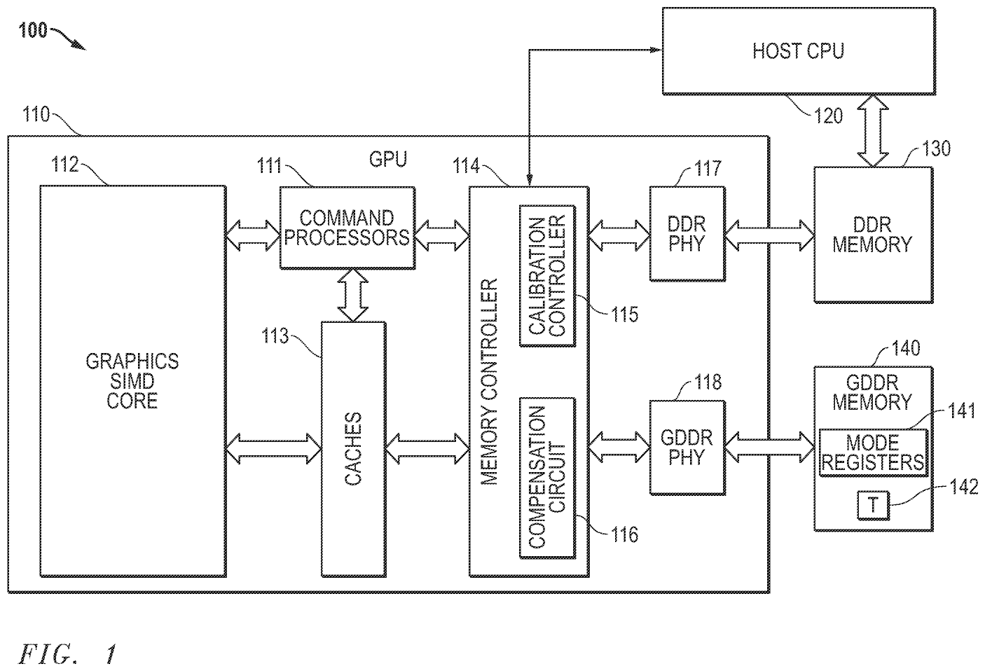

FIG. 1 illustrates in block diagram for a data processing system 100 that compensates for VT drift according to some embodiments. Data processing system 100 includes generally a data processor in the form of a graphics processing unit (GPU) 110, a host central processing unit (CPU) 120, a double data rate (DDR) memory 130, and a graphics DDR (GDDR) memory 140.

GPU 110 is a discrete graphics processor that has extremely high performance for optimized graphics processing, rendering, and display, but requires a high memory bandwidth for performing these tasks. GPU 110 includes generally a set of command processors 111, a graphics single instruction, multiple data (SIMD) core 112, a set of caches 113, a memory controller 114, a DDR physical interface circuit (DDR PHY) 117, and a GDDR PHY 118.

Command processors 111 are used to interpret high-level graphics instructions such as those specified in the OpenGL programming language. Command processors 111 have a bidirectional connection to memory controller 114 for receiving high-level graphics instructions such as OpenGL instructions, a bidirectional connection to caches 113, and a bidirectional connection to graphics SIMD core 112. In response to receiving the high-level instructions, command processors issue low-level instructions for rendering, geometric processing, shading, and rasterizing of data, such as frame data, using caches 113 as temporary storage. In response to the graphics instructions, graphics SIMD core 112 performs low-level instructions on a large data set in a massively parallel fashion. Command processors 111 and caches 113 are used for temporary storage of input data and output (e.g., rendered and rasterized) data. Caches 113 also have a bidirectional connection to graphics SIMD core 112, and a bidirectional connection to memory controller 114.

Memory controller 114 has a first upstream port connected to command processors 111, a second upstream port connected to caches 113, a first downstream bidirectional port to DDR PHY 117, and a second downstream bidirectional port to GDDR PHY 118. As used herein, “upstream” ports are on a side of a circuit toward a data processor and away from a memory, and “downstream” ports are in a direction away from the data processor and toward a memory. Memory controller 114 controls the timing and sequencing of data transfers to and from DDR memory 130 and GDDR memory 140. DDR and GDDR memory have asymmetric accesses, that is, accesses to open pages in the memory are faster than accesses to closed pages. Memory controller 114 stores memory access commands and processes them out-of-order for efficiency by, e.g., favoring accesses to open pages, while observing certain quality-of-service objectives.

DDR PHY 117 has an upstream port connected to the first downstream port of memory controller 114, and a downstream port bidirectionally connected to DDR memory 130. DDR PHY 117 meets all specified timing parameters of the version of DDR memory 130, such as DDR version five (DDR5), and performs timing calibration operations at the direction of memory controller 114. Likewise, GDDR PHY 118 has an upstream port connected to the second downstream port of memory controller 114, and a downstream port bidirectionally connected to GDDR memory 140. GDDR PHY 118 meets all specified timing parameters of the version of GDDR memory 140, and performs timing calibration operations at the direction of memory controller 114.

The interface timing to DDR memory 130 and GDDR memory 140 are susceptible to VT drift. Known techniques for compensation for VT drift center around periodic retraining of the link. However, retraining causes all operations in the system to be stalled while performing the retraining, which may hurt performance and cause jumps and stalls in graphics workloads, diminishing user experience.

In order to overcome the burden of periodic retraining, the inventors have developed various methods for reducing system link sensitivity to VT-induced phase drift. The disclosed VT drift compensation methods reduce, and in some cases eliminate, the need for periodic high-speed link phase retraining. In the exemplary embodiment, the techniques are applied to a GDDR memory interface but they are not restricted to only GDDR memory nor only to memory interfaces.

As shown in FIG. 1, memory controller 114 includes a calibration controller 115 for performing basic link calibration, and a compensation circuit 116 for compensating for VT drift without the need for frequent retraining, thus increasing system performance and improving user experience.

Calibration controller 115 is a circuit that controls calibration of timing parameters for DDR PHY and 117 and GDDR PHY 118. On system startup, the link between DDR PHY 117 and DDR memory 130 has to be trained, and the link between GDDR PHY 118 and GDDR memory 140 is trained. Training generally includes determining the value of a reference voltage used by the memory and PHY to capture input data, the timing relationship between the command clock and data clock(s), and the timing relationship between data and the clock at the sender so that it can be reliably captured by the receiver. Techniques for performing these calibrations are well known and vary based on the DDR and GDDR versions. Moreover, a de facto industry standard for the interface between the memory controller and the memory PHY known as the “DFI” standard has been developed to specify the signaling and characteristics of the interface between the memory controller and the PHY. One of the features of recent versions of the DFI standard is the definition of certain lower-level training features such that most of the calibration functions performed automatically by the PHY, while the overall calibration flow is directed by the memory controller.

In accordance with various embodiments disclosed herein, compensation circuit 116 leverages these capabilities of the PHY circuit such as GDDR PHY 118 to adjust for VT drift without having to do a recalibration operation using calibration controller 115 and GDDR PHY 118. Compensation circuit 116 calculates drifts in timing parameters that are used to control delays in GDDR PHY 118. In one particular embodiment, compensation circuit 116 calculates drifts based on a measured temperature change, at least one voltage sensitivity coefficient, and at least one temperature sensitivity coefficient, and compensates for the timing changes based on these parameters by updating delay amounts of GDDR PHY 118.

GDDR memory 140 includes a set of mode registers 141 and a temperature sensor 142. Mode registers 141 provide a programming interface to control the operation of GDDR memory 140 in the data processing system. As will be explained further below, mode registers 141 store at least one voltage sensitivity coefficient and at least one temperature sensitivity coefficient that are used in VT drift compensation. GDDR memory 140 also includes a temperature sensor for measuring the temperature of GDDR memory 140. In one form, the temperature sensor 142 provides temperature data to compensation circuit 116 in GPU 110 during a refresh operation that ensures that compensation circuit 116 receives updated temperature information periodically.

The inventors have discovered that certain calibrated timing parameters can be adjusted based on measured temperature and voltage differences alone without the need for a performance-impacting recalibration during normal operation. Accordingly, this disclosure describes various methods for reducing system link sensitivity to VT-induced phase drift. The disclosed VT drift compensation methods reduce, and in some cases eliminate, the need for periodic high-speed link phase retraining. This disclosure is presented with respect to a graphics DDR memory interface but is not restricted to only GDDR memory nor only to memory interfaces.

For some GDDR, version 6 (GDDR6) physical layer interface (PHY) systems, voltage and temperature (VT) drift of a parameter known as “WCK2DQI” VT drift direction and magnitude was successfully inferred by monitoring the VT phase drift of an error detection and correction (EDC) lane (WCK2DQO) with respect to a PHY reference clock. As used herein, WSK2DQI means write clock (WCK) to data in delay, and WCK2DQO means WCK_to data-out delay. The PHY reference clock was a branched clock source shared with the error detection and correction (EDC) lane. This basic relationship can be expressed as shown in Equation [1]:

WCK2DQI_drift=WCK2DQO_drift*α [1]

in which α is a scaling factor derived from a hardware evaluation.

Even though many products in use today leverage this WCK2DQI drift correlation to WCK2DQO phase drift, it is not a perfect solution and does not work with all DRAM vendors and applications, and there are several limitations or drawbacks of this method. The inventors herein propose methods to better leverage drift tracking to reduce or eliminate periodic training overhead for high-speed link interfaces, including parameters in GDDR interfaces.

There are two main limitations of the simple model of temperature drift correlation expressed in Equation [1]. First, Equation [1] assumes little to no process variation among DRAM devices. Second, Equation [1] assumes WCK2DQO VT drift symmetrically scales to WCK2DQI for both voltage and temperature sensitivity. In other words, the a scalar must be equivalent for both temperature and voltage, or as expressed in Equation (2):

α_temp=α_volt=WCK2DQI_drift/WCK2QO_drift

The inventors have found that in fact some DRAM devices do not have symmetric correlation between WCK2DQO and WCK2DQI VT drifts. As an example, TABLE I shows VT drift coefficients for write clock to DQ for one such DRAM device:

TABLE I

| Symbol | Parameter | Value | Unit |
|---|---|---|---|
| t_{I2VSENS} | WCK2DQI sensitivity to variations in | −30 | ps/V |
| | VDD, VDDQ | | |
| t_{I2TSENS} | WCK2DQI sensitivity to variations in T_{C} | 0.7 | ps/° C. |

In which ps represents time in picoseconds, V represents voltage in Volts, and Tc represents temperature in degrees Celsius. Note that VDD represents the memory's typical internal power supply voltage at the worst-case processing corner, VDDQ represents the memory's typical input/output power supply voltage at the worst-case processing corner, and Tc represents temperature at the worst-case processing corner.

On the other hand, the measurements are different for VT drift coefficients for write clock to DQ in from the same DRAM vendor, as shown in TABLE II below:

TABLE II

| Symbol | Parameter | Value | Unit |
|---|---|---|---|
| t_{O2VSENS} | WCK2DQO sensitivity to variations in | −180 | ps/V |
| | VDD, VDDQ | | |
| t_{O2TSENS} | WCK2DQO sensitivity to variations in T_{C} | 1.1 | ps/° C. |

As can be seen from TABLES I and II above, Equation (2) does not hold true for this DRAM vendor. The variations for this specific example are described by the following equations:

α_temp=0.7/1.1=0.636

α_volt=−30/−180=0.166

α_avg=(alpha_temp+alpha_volt)/2 Equation (1):

Any determination of WCK2DQI VT drift based on WCK2DQO VT drift using this conventional technique would result in a significant phase tracking error, defined by Equation (4):

Phase tracking error=α_error*WCK2DQ_drift [4]

wherein α_error=abs(α_temp±α_volt)*0.5 and WCK2DQ_drift is the total phase drift observed. The 0.5 multiplier used to derive a error assumes that the asymmetry between voltage and temperature alpha factors are averaged.

So, for example, if there is an observed drift of 100 picoseconds (ps) from WCK2DQO, this drift will result in a phase tracking error on WCK2DQI of 100 ps*0.47/2, which results in an error of 23 ps. This amount of phase tracking error is a significant amount and limits the accuracy and therefore the usefulness of existing phase tracking techniques based on Equation [2]. Moreover, this amount was computed without process mismatch terms for different DRAMs of the same vendor product line being considered.

The inventors of the present disclosure have developed new methods and apparatus to overcome these aforementioned limitations. The source of these limitations will be described with respect to a typical GDDR memory PHY to GDDR memory link, which will now be described.

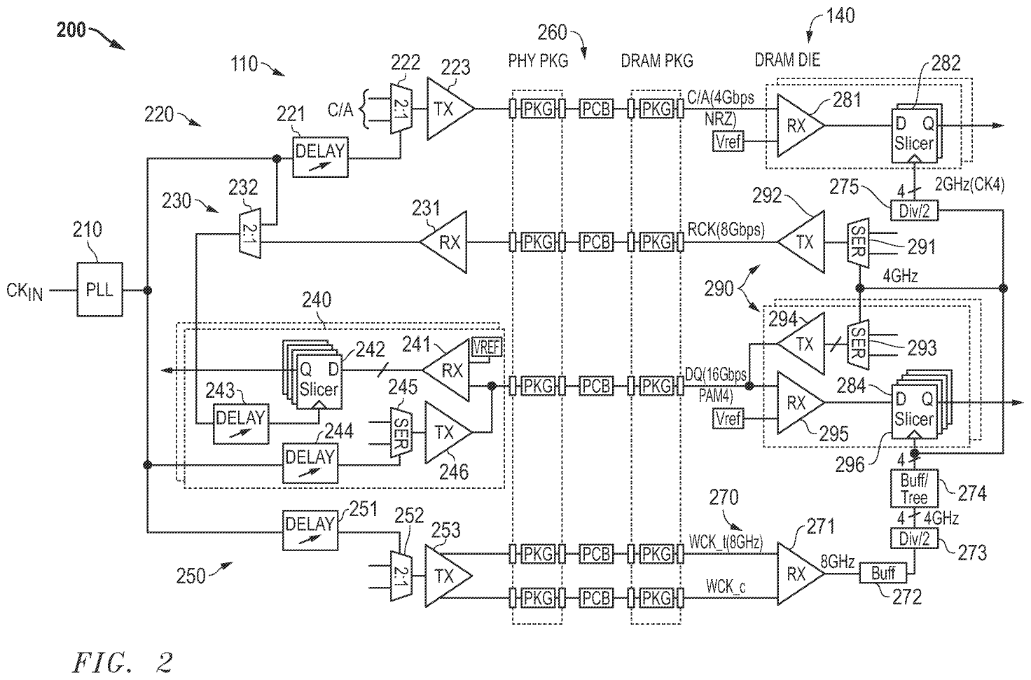

FIG. 2 illustrates in block diagram form a GDDR PHY-DRAM link 200 of data processing system 100 of FIG. 1 according to some embodiments. GDDR PHY-DRAM link 200 includes portions of GPU 110 and GDDR memory 140 that communicate over a physical interface 260.

GPU 110 includes a phase locked loop (PLL) 210, a command and address (“C/A”) circuit 220, a read clock circuit 230, a data circuit 240, and a write clock circuit 250. These circuits form part of GDDR PHY 118 of GPU 110.

Phase locked loop 210 operates as a reference clock generation circuit and has an input for receiving an input clock signal labelled “CKIN”, and an output.

C/A circuit 220 includes a delay element 221, a selector 222, and a transmit buffer 223 labelled “TX”. Delay element 221 has an input connected to the output of PLL 210, and an output, and has a variable delay controlled by an input, not specifically shown in FIG. 2. The variable delay is determined at startup by calibration controller 115 and adjusted during operation by compensation circuit 116 according to the techniques described herein. Selector 222 has a first input for receiving a first command/address value, a second input for receiving a second command/address value, and a control input connected to the output of delay element 221. Transmitter 223 has an input connected to the output of selector 222, and an output connected to a corresponding integrated circuit terminal for providing a command/address signal labelled “C/A” thereto. Note that C/A circuit 220 includes a set of individual buffers for each signal in the C/A signal group that are constructed the same as the representative selector 222 and buffer 223 shown in FIG. 2, but only a representative C/A circuit 220 is shown.

Read clock circuit 230 include a receive buffer 231 labelled “RX”, and a selector 232. Receive buffer 231 has an input connected to a corresponding integrated circuit terminal for receiving a signal labelled “RCK”, and an output. Receive clock selector 232 has a first input for connected to the output of PLL 210, a second input connected to the output of receive buffer 231, an output, and a control input for receiving a mode signal, not shown in FIG. 2.

Data circuit 240 includes a receive buffer 241, a latch 242, delay elements 243 and 244, a serializer 245, and a transmit buffer 246. Receive buffer 241 has a first input connected to an integrated circuit terminal that receives a data signal labelled generically as “DQ”, a second input for receiving a reference voltage labelled “VREF”, and an output. Latch 242 is a D-type latch having an input labelled “D” connected to the output of receive buffer 241, a clock input, and an output labelled “Q” for providing an output data signal. The interface between GDDR PHY 118 and GDDR memory 140 implements a four-level, pulse amplitude modulation data signaling system known as “PAM-4”, which encodes two data bits into one of four nominal voltage levels. Thus, receive buffer 241 discriminates which of the four levels is indicated by the input voltage, and outputs two data bits to represent the state in response. For example, receive buffer 241 could generate three slicing levels based on VREF defining four ranges of voltages, and use three comparators to determine which range the received data signal falls in. Data circuit 240 includes latches which latch the two data bits and is replicated for each bit position. Delay element 243 has an input connected to the output of selector 232, and an output connected to the clock input of latch 242. Delay element 244 has an input connected to the output of PLL 210, and an output. Serializer 245 has inputs for receiving a first data value of a given bit position and a second data value of the given bit position, the first and second data values corresponding to sequential cycles of a burst, a control input connected to the output of delay element 244, and an output connected to the corresponding DR terminal. Each data byte of the data bus has a set of data circuits like data circuit 240 for each bit of the byte. This replication allows different data bytes that have different routing on the printed circuit board to have different delay values.

Write clock circuit 250 includes a delay element 251, a selector 252, and a transmit buffer 253. Delay element 251 has an input connected to the output of PLL 210, and an output. Selector 252 has a first input for receiving a first clock state signal, a second input for receiving a second clock voltage, a control input connected to the output of delay element 251, and an output. Transmit buffer 253 has an input connected to the output of selector 252, and an output a first output connected to a corresponding integrated circuit terminal for providing a true write clock signal labelled “WCK_t” thereto, and a second output connected to a corresponding integrated circuit terminal for providing a complement write clock signal labelled “WCK_c” thereto.

GDDR memory 140 includes generally a write clock receiver 270, a command/address receiver 280, and a data path transceiver 290. Write clock receiver 270 includes a receive buffer 271, a buffer 272, a divider 273, a buffer/tree 274, and a divider 275. Receive buffer 271 has a first input connected to an integrated circuit terminal of GDDR memory 140 that receives the WCK_t signal, a second input connected to an integrated circuit terminal of GDDR memory 140 that receives the WCK_c signal, and an output. In the example shown in FIG. 2, the output of receive buffer 271 is clock signal having a nominal frequency of 8 GHz. Buffer 272 has an input connected to the output of receive buffer 271, and an output. Divider 273 has an input connected the output of buffer 272, and an output for providing a divided clock having a nominal frequency of 4 GHz. Divider 275 has an input for connected to the output of buffer/tree 274, and an output for providing a clock signal labelled “CK4” having a nominal frequency of 2 GHz.

Command/address receiver 280 includes a receive buffer 281 and a slicer 282. Receive buffer 281 has a first input connected to a corresponding integrated circuit terminal of GDDR memory 140 that receives the C/A signal, a second input for receiving VREF, and an output. The C/A input signal is received as a normal binary signal having two logic states levels and is considered a non-return-to-zero (NRZ) signal encoding. Slicer 282 has a set of two data latches each having a D input connected to the output of receive buffer 281, a clock input for receiving a corresponding one of the output of divider 275, and a Q output for providing a corresponding C/A signal.

Data path transceiver 290 includes a serializer 291, a transmitter 292, a serializer 293, a transmitter 294, a receive buffer 295, and a slicer 296. Serializer 291 has an input for receiving a first read clock level, a second input for receiving a second read clock level, a select input connected to the output of buffer/tree 274, and an output. Transmitter 292 has an input connected to the output of serializer 293, and an output connected to the RCK_terminal of GDDR memory 140. Serializer 293 has an input for receiving a first read data value, a second input for receiving a second data value, a select input connected to the output of buffer/tree 274, and an output. Transmitter 294 has an input connected to the output of serializer 293, and an output connected to the corresponding DQ terminal of GDDR memory 140. Receive buffer 295 has a first input connected to the corresponding DQ terminal of GDDR memory 140, a second input for receiving the VREF value, and an output. Slicer 296 has a set of four data latches each having a D input connected to the output of receive buffer 295, a clock input connected to the output of buffer/tree 274, and a Q output for providing a corresponding DQ signal.

Interface 260 includes a set of physical connections that are routed between a bond pad of the GPU 110 die, through a package impedance to a package terminal, through a trace on a printed circuit board, to a package terminal of GDDR memory 140, through a package impedance, and to a bond pad of the GDDR memory 140 die.

In operation, data processing system can be used as a graphics card or accelerator because of the high bandwidth graphics processing performed by graphics SIMD core 112. Host CPU 120, running an operating system or an application program, sends graphics processing commands to CPU 110 through DDR memory 130, which serves as a unified memory for GPU 110 and host CPU 120. It may send the commands using, for example, as OpenGL commands, or through any other host CPU to GPU interface. OpenGL was developed by the Khronos Group, and is a cross-language, cross-platform application programming interface for rendering 2D and 3D vector graphics. Host CPU 120 uses an application programming interface (API) to interact with GPU 110 to provide hardware-accelerated rendering.

Data processing system 100 uses two types of memory. The first type of memory is DDR memory 130, and is accessible by both GPU 110 and host CPU 120. As part of the high performance of graphics SIMD core 112, GPU 110 uses a high-speed graphics double data rate (GDDR) memory.

In high-speed DDR memories, read or write data can have variable transmission path delays that change with respect to the clock signal that is used to latch the data elements. Moreover, the JEDEC committee has specified that the processor will calibrate the link such that the data elements can be properly transferred between the data processor and the memory to perform the series of data elements delays between GPU 110 and GDDR memory 140. The various signal processing paths lengths inject skew into the system such that as VT change during operation, the drifts in various signal paths do not track each other such that a simple temperature scaling adjustment shown in Equation [2] does not produce accurate compensated calibration values. This property will now be described.

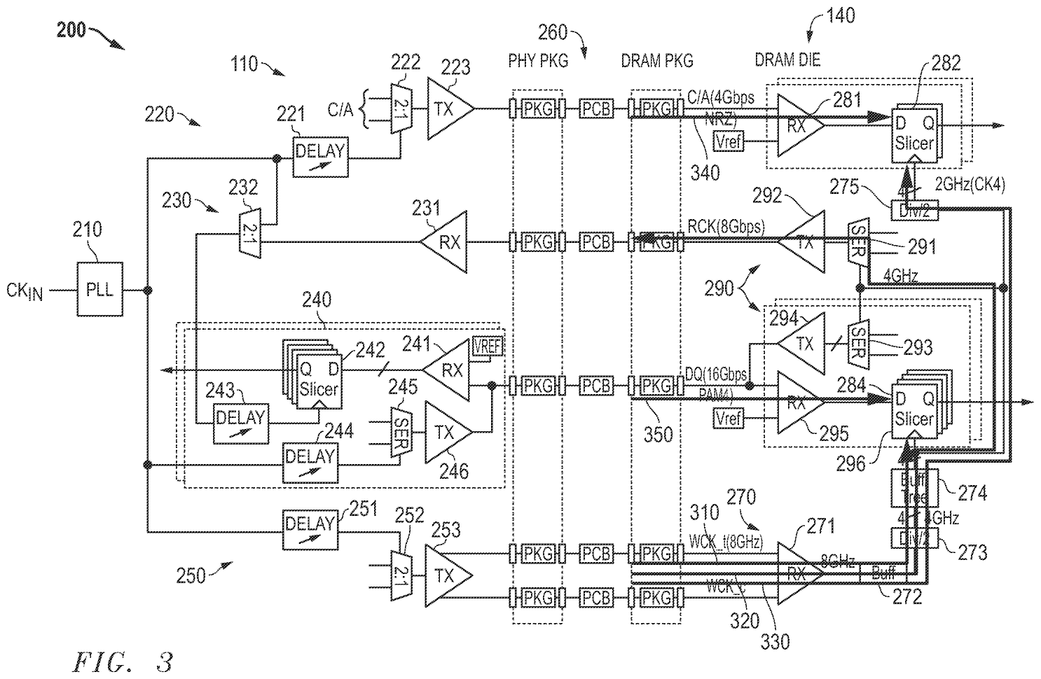

FIG. 3 illustrates in block diagram form an annotated GDDR PHY-DRAM link 300 corresponding to GDDR PHY-DRAM link 200 of FIG. 2. GDDR PHY-DRAM link 300 has been annotated to show signal paths that account for certain timing differences according to VT changes.

A timing path 310 shows the path of the write clock formed by differential signals WCK_t and WCK_c to the capture of input (write) data in slicer 296. Timing path 310 shows the received write clock flows through the DRAM package, receive buffer 271, buffer 272, divider 273, and buffer/tree 274 before it arrives at the clock input of slicer 296. A timing path 350 shows the path of the data input signal during a write cycle and shows the received data flows through the DRAM package impedance, and receive buffer 283 to the input of slicer 284. Timing path 310 goes through more circuitry than timing path 350 and changes in VT affect it more than changes in timing path 350. These path delays affect the timing parameter known as WCK2DQI.

A timing path 320 shows the path of the write clock to the output of the read clock RCK. Timing path 320 shows the received write clock flows through the DRAM package resistance receive buffer 271, buffer 272, divider 273, buffer/tree 274, divider 275, serializer 291, transmit buffer 292, and the package impedance to form the read clock. This path delay determines the timing parameter known as WCK2RCK.

A timing path 330 shows the path of the write clock to the capture of the command/address signals in slicer 296. Timing path 320 shows the received write clock flows through the DRAM package impedance, receive buffer 271, buffer 272, divider 273, buffer/tree 274, and divider 275 before it arrives at the clock input of slicer 282. A timing path 340 shows the path of the C/A input signal during a command cycle and shows the received data flows through the DRAM package, and receive buffer 281 to the input of slicer 282. This path affects the timing parameter known as WCK2CA. Timing path 330 goes through more circuitry than timing path 340, and changes in VT affect it more than changes in timing path 340. These path delays affect the timing parameter known as WCK2CA.

These representative circuit diagrams illustrate that VT drift will affect each of these paths differently. For example, propagation time through a package routing path would be affected by temperature but not by the memory's power supply voltages. On the other hand, propagation time through active circuitry would be affected not only by temperature but also by power supply voltage.

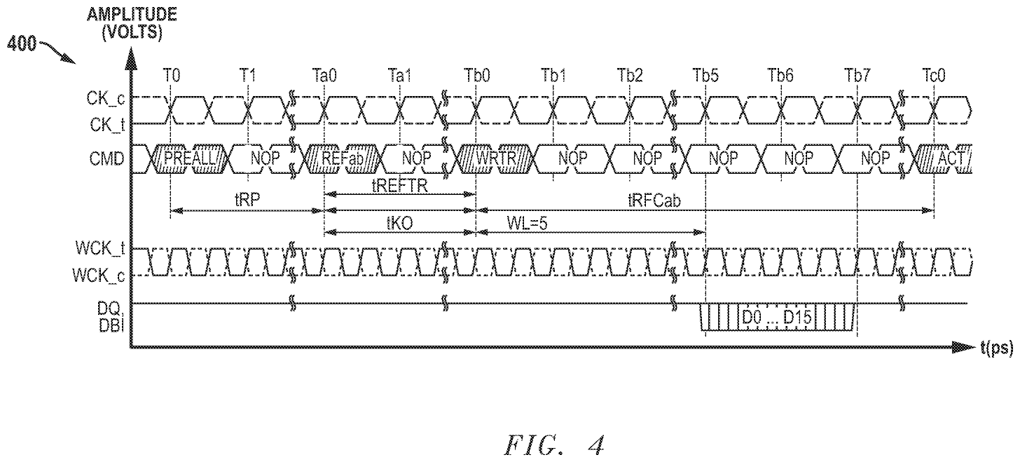

FIG. 4 illustrates a timing diagram 400 useful in understanding how to capture the WCK2RCK drift parameter without impacting system performance or latency. In timing diagram 400, the horizontal axis represents time in picoseconds (ps), and the vertical axis represents the amplitude of several signals in volts (V). Timing diagram 400 shows a waveform of a differential clock signal formed by true and complement clock signals CK_t and CK_c. The differential clock signal is used to latch a command signal labelled “CMD” and address signals (not shown in FIG. 4) in GDDR memory 140. In order to ensure that the commands are reliably captured at the memory, calibration controller 115 of FIG. 1 previously performed command/address training to determine the amount of delay between the two signal groups is applied by GDDR PHY 118 such that the CMD and address signals arrive at the inputs to GDDR memory 140 near the center of the data “eye” with adequate setup and hold time relative to the transitions in the CK_t and CK_c signals. Thus, at a time labelled “TO”, a precharge all command PREALL is latched by GDDR memory 140, a refersh all banks (REFab) command is latched at a time labelled “Ta0”, and a write training command (WRTR) is latched at a time labelled “Tb0”. In response to the WRTR command, GDDR memory 140 provides read data that can be compared with expected read data, and GDDR PHY 118 can incrementally change the delay of delay element 251 until the expected read data is returned on from GDDR memory 140 on the DQ pins, defining the current WCK2RCK drift. Thus, calibration controller 115 can perform incremental write training to find the WCK2RCK drift parameter during one or more refresh all bank periods while GDDR memory 140 cannot perform any pending read or write operation.

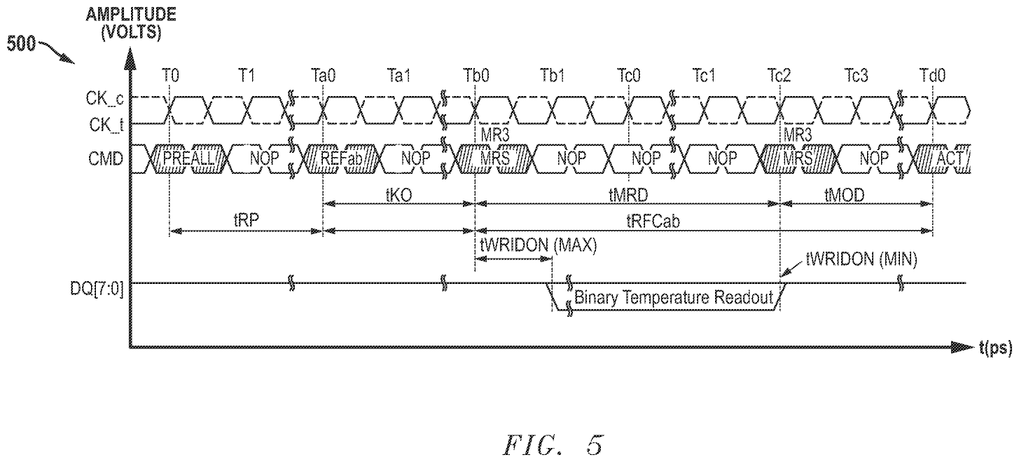

FIG. 5 illustrates a timing diagram 500 useful in understanding how to read the memory temperature without impacting system performance or command latency. In timing diagram 500, the horizontal axis represents time in picoseconds (ps), and the vertical axis represents the amplitude of several signals in volts (V). Timing diagram 500 shows a waveform of a differential clock signal formed by true and complement clock signals CK_t and CK_c. The differential clock signal is used to latch a command signal labelled “CMD” signal and address signals (not shown in FIG. 5) in GDDR memory 140. In order to ensure that the commands are reliably captured at the memory, calibration controller 115 of FIG. 1 has previously performed command/address training to determine the amount of delay between the two signal groups is applied by GDDR PHY 118 such that the CMD and address signals arrive at the inputs to GDDR memory 140 near the center of the data eye with adequate setup and hold time relative to the transitions in the CK_t and CK_c signals. Thus, at a time labelled “TO”, a precharge all command PREALL is latched by GDDR memory 140, a refresh all banks (REFab) command is latched at a time labelled “Ta0”, and a mode register set command (MRS) is latched at a time labelled “Tb0”. This MRS command reads a mode register that holds a temperature value of the memory.

For example, the mode register set command is a command that writes to particular bits of a particular mode register of GDDR4 memory 140 to invoke a temperature readout operation. GDDR memory 140 provides the temperature readout derived from temperature sensor 142 on DQ pins 7:0. GDDR memory 140 keeps the DQ pins stable for an extended period of time to allow the temperature to be read before initial timing calibration. In the illustrated embodiment, GDDR memory 140 provides a Binary Temperature Readout within a maximum of a time tWRIDON following Tb0. GDDR memory 140 drives the Binary Temperature Readout on DQ[7:0] until at least the receipt of an MRS command that disables the Binary Temperature Readout at time Tc2 which can be provided as early as a time tMRD after Tb0 as shown in FIG. 5. Thus, calibration controller 115 can perform temperature readout to determine the DRAM_deltaTemp parameter during one refresh all bank period when GDDR memory 140 cannot perform any pending read or write operation.

According to some embodiments, calibration controller 115 in memory controller 114 has the flexibility to leverage drift tracking information from WCK2RCK in combination with other VT compensation methods. For example, if the phase drift registered from the WCK2RCK drift exceeds a threshold, then calibration controller 115 could optionally trigger a full Write/Read/CA calibration. This full calibration could be used to update VT sensitivity coefficients. To facilitate this technique, calibration controller 115 may extract multiple voltage and temperature drift magnitudes throughout device operation and update one or more offsets to better predict VT behavior in the future.

To fully leverage the VT sensitivity information stored in mode registers 141, an allowed error tolerance is set as well as maximum drift thresholds that cause the UMC to issue full link-retraining when necessary. An exemplary a set of parameters that can be used for this process is shown in TABLEs III-V.

TABLE III corresponds to GDDR DRAM Reference RX (Write) operations at 32 Gbps transfer speeds:

TABLE III

| Assumptions | MIN | MAX | Units | Comments |
|---|---|---|---|---|
| WCKDQ0DQ2Latch | — | 250 | ps | To limit sensitivity |
| Insertion Delay | | | | to PLL phase noise |
| DQ2DQI Skew with | −40 | 40 | ps | Maximum skew |
| respect to WCK | | | | from DQ to DQ |
| | | | | WRT WCK at DQ |
| | | | | latch (incl. PKG) |
| WCK2DQI | −0.5 | 0.5 | ps/° C. | DQ to DQ VT |
| Temperature | | | | sensitivity is |
| Sensitivity | | | | assumed to be |
| | | | | negligible |
| WCK2DQI Voltage | −0.2 | 0.2 | ps/mV | DQ to DQ VT |
| Sensitivity | | | | sensitivity is |
| | | | | assumed to be |
| | | | | negligible |
| WDCKI_terr | −0.02 | 0.02 | ps/° C. | Constrain VT |
| Temperature | | | | sensitivity |
| Sensitivity | | | | coefficient to |
| Error Tolerance | | | | Mode Register |
| | | | | lookup table |
| WDCKI_verr Voltage | −0.02 | 0.02 | ps/mV | Constrain VT |
| Sensitivity Error | | | | sensitivity |
| Tolerance | | | | coefficient to |
| | | | | Mode Register |
| | | | | lookup table |

TABLE IV corresponds to GDDR DRAM Reference TX (Read) Operations at 32 Gbps transfer speeds:

TABLE IV

| Assumptions | MIN | MAX | Units | Comments |
|---|---|---|---|---|
| DQ2DQ0 skew with | −25 | 25 | ps | Maximum skew from |
| respect to RCK | | | | DQ to DQ WRT RCK |
| | | | | at package ball |
| RCK2DRO | −0.02 | 0.02 | ps/° C. | RCK and DQ are |
| Temperature | | | | assumed to be |
| Sensitivity | | | | matched paths |
| | | | | within the DRAM |
| RCK2DRO Voltage | −0.02 | 0.02 | ps/mV | RCK and DQ are |
| Sensitivity | | | | assumed to be |
| | | | | matched paths |
| | | | | within the DRAM |
| WCK2RCK | −0.9 | 0.9 | ps/° C. | |
| Temperature | | | | |
| Sensitivity | | | | |
| WCK2RCK Voltage | −0.5 | 0.5 | ps/mV | |
| Sensitivity | | | | |
| WCK2DQI_terr | −0.04 | 0.04 | ps/° C. | Constrain VT sensi- |
| Temperature | | | | tivity coefficient |
| Sensitivity | | | | to Mode Register |
| Error Tolerance | | | | lookup table |
| WCK2DQI_verr | −0.02 | 0.02 | ps/mV | Constrain VT sensi- |
| Voltage | | | | tivity coefficient |
| Sensitivity Error | | | | to Mode Register |
| Tolerance | | | | lookup table |

TABLE V corresponds to GDDR DRAM C/A Timing Reference Operations at 32 Gbps transfer speeds:

TABLE V

| Assumptions | MIN | MAX | Units | Comments |
|---|---|---|---|---|
| WCK2CA | −0.75 | 0.75 | ps/° C. | CA to CA VT sensi- |
| Temperature | | | | tivity is assumed to |
| Sensitivity | | | | be negligible |
| WCK2CA Voltage | −0.4 | 0.4 | ps/mV | CA to CA VT sensi- |
| Sensitivity | | | | tivity is assumed |
| | | | | to be negligible |
| WCK2CA_terr | −0.03 | 0.03 | ps/° C. | Constrain VT sensi- |
| Temperature | | | | tivity coefficient |
| Sensitivity | | | | to Mode Register |
| Error Tolerance | | | | lookup table |
| WCK2CA_verr Voltage | −0.02 | 0.02 | ps/mV | Constrain VT sensi- |
| Sensitivity Error | | | | tivity coefficient |
| Tolerance | | | | to Mode Register |
| | | | | lookup table |

A data processing system or portions thereof described herein can be embodied one or more integrated circuits, any of which may be described or represented by a computer accessible data structure in the form of a database or other data structure which can be read by a program and used, directly or indirectly, to fabricate integrated circuits. For example, this data structure may be a behavioral-level description or register-transfer level (RTL) description of the hardware functionality in a high-level design language (HDL) such as Verilog or VHDL. The description may be read by a synthesis tool which may synthesize the description to produce a netlist including a list of gates from a synthesis library. The netlist includes a set of gates that also represent the functionality of the hardware including integrated circuits. The netlist may then be placed and routed to produce a data set describing geometric shapes to be applied to masks. The masks may then be used in various semiconductor fabrication steps to produce the integrated circuits. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, the embodiments have been described with reference to a graphics double data rate (GDDR) DRAM, but can also be applied to other memory types including non-graphics DDR memory, high-bandwidth memory (HBM), and the like. Moreover while they have been described with reference to a data processing system having a discrete GPU for very high performance graphics operations, they can also be applied to a data processing system with an accelerated processing unit (APU) in which the CPU and GPU are incorporated together on a single integrated circuit chip. The use differential signaling or single-ended signaling, and NRZ data signaling or PAM-4 signaling, can also vary in different embodiments.

Accordingly, it is intended by the appended claims to cover all modifications of the disclosed embodiments that fall within the scope of the disclosed embodiments.

What is claimed is:

1. A data processing system comprising a data processor coupled to a memory, the data processor comprising:
a reference clock generation circuit for providing a reference clock signal;
a first delay circuit for delaying said reference clock signal by a first amount to provide a command and address signal;
a second delay circuit for delaying said reference clock signal by a second amount to provide a read data signal;
a calibration circuit for determining current values of said first and second amounts; and
a compensation circuit for calculating drifts in said first and second amounts based on a measured temperature change, at least one voltage sensitivity coefficient, and at least one temperature sensitivity coefficient, and for updating said first and second amounts according to said drifts.

2. The data processing system of claim 1, wherein said compensation circuit calculates said drifts in said first and second amounts further based on a timing drift between a write clock signal provided to the memory and a read clock signal received from the memory.

3. The data processing system of claim 1, wherein said calibration circuit comprises:
a calibration controller for issuing memory operations to determine said current values; and
a memory physical layer interface circuit (PHY) coupled to said calibration controller for providing signals to said memory in response to said memory operations.

4. The data processing system of claim 1, wherein the memory comprises:
a mode register for storing said at least one voltage sensitivity coefficient and said at least one temperature sensitivity coefficient.

5. The data processing system of claim 1, wherein the memory comprises:
a temperature sensor for measuring a temperature of the memory,
wherein the memory provides said temperature to the data processor during a predetermined operation.

6. The data processing system of claim 5, wherein said predetermined operation comprises a refresh operation.

7. The data processing system of claim 1, wherein:
said compensation circuit causes said calibration circuit to perform a full link retraining sequence in response to said drifts of either of said first and second amounts exceeding a respective allowed threshold.

8. A data processor adapted to be coupled to a memory, comprising:
a reference clock generation circuit for providing a reference clock signal;
a first delay circuit for delaying said reference clock signal by a first amount to provide a command and address signal;
a second delay circuit for delaying said reference clock signal by a second amount to provide a read data signal;
a calibration circuit for determining current values of said first and second amounts; and
a compensation circuit for calculating drifts in said first and second amounts based on a measured temperature change, at least one voltage sensitivity coefficient, and at least one temperature sensitivity coefficient, and for updating said first and second amounts according to said drifts.

9. The data processor of claim 8, wherein said compensation circuit calculates said drifts in said first and second amounts further based on a timing drift between a write clock signal provided to the memory and a read clock signal received from the memory.

10. The data processor of claim 8, wherein said calibration circuit comprises:
a calibration controller for issuing memory operations to determine said current values; and
a memory physical layer interface circuit (PHY) coupled to said calibration controller for providing signals to said memory in response to said memory operations.

11. The data processor of claim 8, wherein the compensation circuit is adapted to read said at least one voltage sensitivity coefficient and said at least one temperature sensitivity coefficient from at least one mode register of the memory.

12. The data processor of claim 8, wherein:
said compensation circuit causes said calibration circuit to perform a full link retraining sequence in response to said drifts of either of said first and second amounts exceeding a respective allowed threshold.

13. A method for a data processor to update timing values for accessing a memory to compensate for voltage and temperature (VT) drift during operation without performing link retraining, comprising:
generating a reference clock signal;
delaying said reference clock signal by a first amount using a first delay circuit to provide a command and address signal;
delaying said reference clock signal by a second amount using a second delay circuit to provide a read data signal;
determining current values of said first and second amounts using a calibration circuit; and
calculating drifts in said first and second amounts based on a measured temperature change, at least one voltage sensitivity coefficient, and at least one temperature sensitivity coefficient using a compensation circuit.

14. The method of claim 13, further comprising:
calculating said drifts in said first and second amounts further based on a timing drift between a write clock signal provided to the memory and a read clock signal received from the memory.

15. The method of claim 14, further comprising:
measuring said timing drift between said write clock signal provided to the memory and said read clock signal received from the memory during a read cycle.

16. The method of claim 14, further comprising:
measuring said timing drift between said write clock signal provided to the memory and said read clock signal received from the memory during a refresh period.

17. The method of claim 14, further comprising:
measuring said timing drift between said write clock signal provided to the memory and said read clock signal received by setting a mode register of the memory to place the read clock signal into a continuous toggle mode.

18. The method of claim 13, further comprising:
measuring a temperature of the memory,
providing said temperature to the data processor during a predetermined operation.

19. The method of claim 18, wherein providing said temperature to the data processor during said predetermined operation comprises:
providing said temperature to the data processor during a refresh operation of the memory.

20. The method of claim 13, further comprising:
causing said calibration circuit to perform a full link retraining sequence in response to said drifts of either of said first and second amounts exceeding a respective allowed threshold.
